(19) United States
(12) Patent Application Publication
(10) Pub. No.: US 2005/0287743 A1
(43) Pub. Date: Dec. 29, 2005

(54) Method of manufacturing semiconductor device having recess channel structure

(75) Inventor: Ho Ung Kim, Gyunggi-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/038,559

(22) Filed: Jan. 18, 2005

(30) Foreign Application Priority Data
Jun. 24, 2004 (KR) 2004-47586

(51) Int. Cl. H01L 21/336

(52) U.S. Cl. 438/259

(57) ABSTRACT

Disclosed herein is a method of manufacturing a semiconductor device having a recess channel structure, which prevents misalignment of a source/drain, thereby being capable of achieving an improvement in the drive-ability of a gate and preventing a degradation in characteristics of the semiconductor device due to a hot carrier effect. The method comprises the steps of forming a threshold voltage adjustment ion layer having a predetermined depth in an active region of a silicon substrate, implanting source/drain forming ions into the silicon substrate on the threshold voltage adjustment ion layer formed in the silicon substrate, forming a mask, which defines a recess trench forming region, on the silicon substrate, after completing the implantation of the source/drain forming ions, forming recess trenches by etching the silicon substrate to a predetermined depth using the mask as an etching mask, depositing polysilicon on the silicon substrate to a thickness sufficient to bury the recess trenches, and forming a gate electrode through planarization of the deposited polysilicon.

### BACKGROUND OF THE INVENTION

Field of the Invention

The present invention relates to a method of manufacturing a semiconductor device, and more particularly to a method of manufacturing a semiconductor device having a recess channel structure, which prevents misalignment of a source/drain, thereby being capable of achieving an improvement in the drive-ability of a gate and preventing a degradation in characteristics of the semiconductor device due to a hot carrier effect.

Description of the Related Art

Nowadays, in response to a reduction in the design rule of a semiconductor device due to highly integrated DRAM memory cells, a cell transistor is reduced in size and the channel length thereof. Such a reduced channel length exacerbates a short-channel effect of the transistor, lowering a threshold voltage.

Conventionally, in order to prevent the threshold voltage from lowering due to the short-channel effect of the transistor, it has been proposed to increase a doping density of the channel, achieving a desired level of the threshold voltage.

However, the greater channel doping density is problematic since it causes electric field concentration in source junctions and induces the high leakage current, resulting in a degradation in a refresh characteristic of the DRAM memory cells.

Therefore, as a solution to the above problems, recent study is concentrated on a transistor having a recess gate.

Now, a method of manufacturing a semiconductor device having a recess channel structure according to the prior art will be explained in detail with reference to FIGS. 1a to 1d.

FIGS. 1a to 1d are front sectional views illustrating sequential processes of the semiconductor device manufacturing method according to the prior art.

Referring first to FIG. 1a, device isolation region is formed on semiconductor substrate, wherein substrate defines an active region and device isolating region.

Next, threshold voltage adjustment ions are implanted into the active region of the silicon substrate 1 to form a threshold voltage adjustment ion layer 3 having a predetermined thickness.

Referring to FIG. 1b, after the threshold voltage adjustment ion layer 3 is formed on the silicon substrate 1, a first photoresist 4 for forming trenches T is formed on the silicon substrate 1. Then, as the silicon substrate 1 and the threshold voltage adjustment ion layer 3 are partially etched using the first photoresist 4 as an etching mask, a plurality of the trenches T are formed.

Referring to FIG. 1c, polysilicon (not shown) is deposited on the silicon substrate 1 to bury the trenches T, and then is planarized, thereby forming a polysilicon gate electrode 5.

Referring to FIG. 1d, on the resulting structure formed with the gate electrode 5 is formed a second photoresist 7, which is patternized so that a partial region thereof between the trenches T is opened. Finally, ions are implanted through the opened region of the second photoresist 7, which serves as an ion implantation mask, thereby forming a source/drain 6 in the silicon substrate 1 on the threshold voltage adjustment ion layer 3.

In the above described semiconductor device manufacturing method according to the prior art, however, since the ion implantation process for forming the source/drain is performed after forming the gate, it is difficult to achieve an accurate alignment between the previously formed gate and the ion implantation mask for forming of the source/drain.

If the gate is misaligned with the ion implantation mask for forming of the source/drain, it disables proper formation of the source/drain, causing a deterioration in the drive-ability of the gate.

Furthermore, the manufacturing method of the prior art inevitably produces a defective semiconductor device since the ion implantation process for forming the source/drain requires a high voltage (normally in a range of 20 to 40 KeV). The defective semiconductor device shows a low refresh characteristic and an increased degradation due to a hot-carrier effect.

### SUMMARY OF THE INVENTION

Therefore, the present invention has been made in view of the above problems, and it is an object of the present invention to provide a method of manufacturing a semiconductor device having a recess channel, which can improve shot channel and prevent the misalignment of a resulting source/drain.

In according to an aspect of the present invention, the above and other objects can be accomplished by the provision of a method of manufacturing a semiconductor device comprising the steps of: a) forming a threshold voltage adjustment ion layer having a predetermined depth in an active region of a silicon substrate; b) implanting source/drain forming ions into the silicon substrate on the threshold voltage adjustment ion layer formed in the silicon substrate; c) forming a mask for defining a recess trench forming region on the silicon substrate, where in substrate complete the implantation of the source/drain forming ions; d) forming recess trenches by etching the silicon substrate to a predetermined depth using the mask as an etching mask; e) depositing polysilicon on the silicon substrate to a thickness sufficient to bury the recess trenches; and f) forming a gate electrode through planarization of the deposited polysilicon.

Preferably, the source/drain forming ions may be implanted into the silicon substrate by making use of a voltage in a range of 10 to 20 KeV.

Preferably, the bottom of the trenches may be higher than the bottom of the threshold voltage adjustment ion layer on the silicon substrate.

That is, according to the present invention, in the manufacture of the semiconductor device having a recess channel structure, as a result of forming the threshold voltage adjustment ion layer and the source/drain prior to formation of the gate, it is possible to prevent the misalignment of the source/drain due to the conventional misalignment problem of the mask.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1d are front sectional views illustrating a method of manufacturing a semiconductor device in accordance with the prior art; and

FIGS. 2a to 2c are front sectional views illustrating a method of manufacturing a semiconductor device in accordance with the present invention.

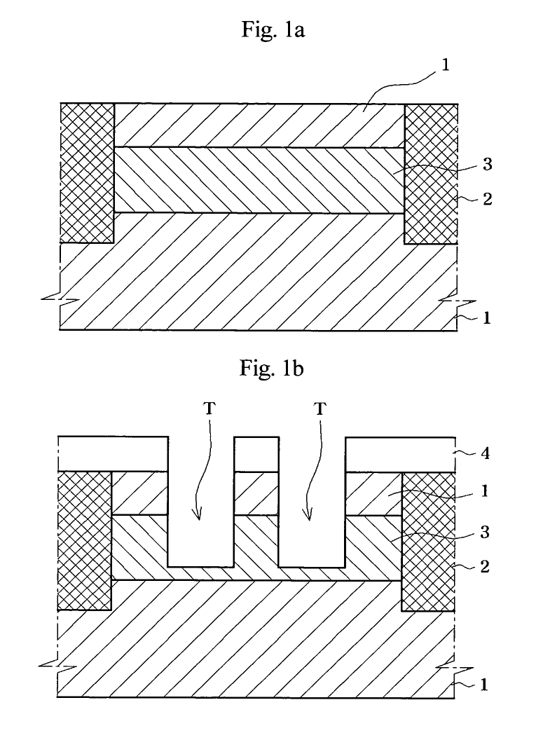

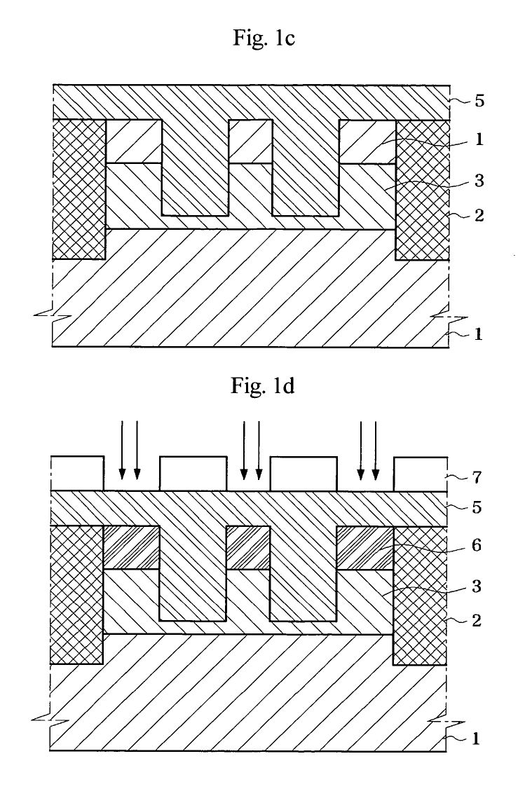

### DESCRIPTION OF THE PREFERRED EMBODIMENTS

Now, a preferred embodiment of the present invention will be explained. It should be understood that the description of the embodiment is only for exemplary, and the scope of the present invention should not be limited to the description of the embodiment.

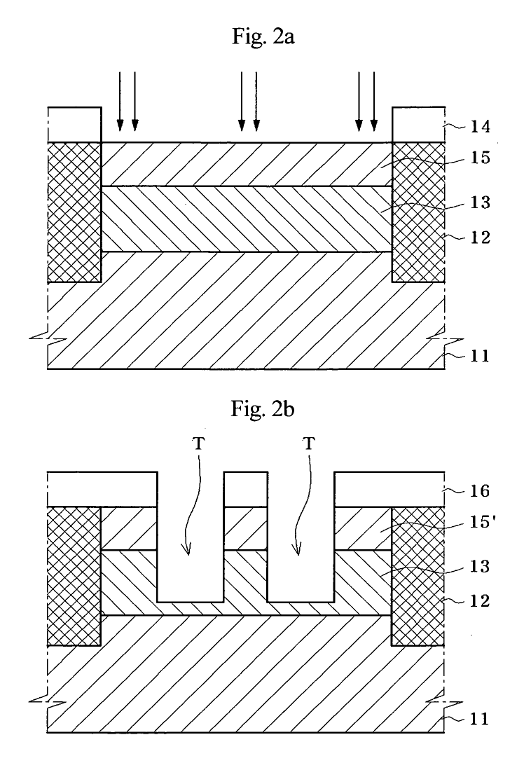

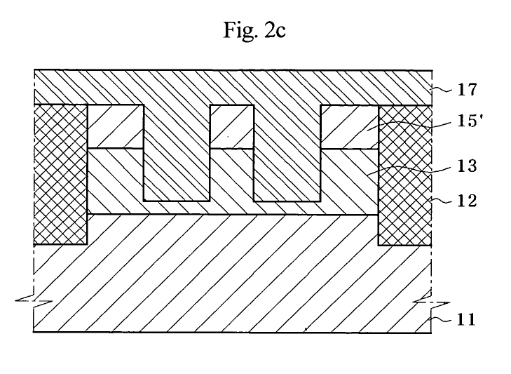

FIGS. 2a to 2c are front sectional views illustrating a method of manufacturing a semiconductor device in accordance with the present invention.

Referring first to FIG. 2a, device isolation region is formed on semiconductor substrate(11), wherein substrate defines an active region and device isolating region.

Immediately after threshold voltage adjustment ions are implanted into the active region of the silicon substrate 11 to form a threshold voltage adjustment ion layer 13 having a predetermined thickness, ions for forming of a source/drain are implanted to form a source/drain ion layer 15 on the threshold voltage adjustment ion layer 13. Here, the ions used to form a source/drain are implanted using a low voltage, for example, in a range of 10 to 20 KeV, in order to prevent production of a defective device due to the conventional high voltage, for example, in the range of 20 to 40 KeV. Preventing the production of defective devices due to the high voltage has the effect of improving a refresh characteristic of the resulting device and preventing a degradation in characteristics of the device due to a hot carrier effect.

In the above description, not explained reference numeral 14 denotes a mask configured to close the device region and open only the active region. The mask 14 serves as an ion implantation mask for using the implantation of both the threshold voltage adjustment ions and the source/drain forming ions.

Next, as shown in FIG. 2b, on the top of the silicon substrate 11, in which the threshold voltage adjustment ion layer 13 and the source/drain ion layer 15 were formed, is formed a mask 16 defining a recess trench forming region.

As the silicon substrate 11 is partially etched by a predetermined depth using the mask 16 as an etching mask, a plurality of trenches T are formed. The trenches T are recesses for forming of a gate. In this case, the bottom of the trenches T is higher than the bottom of the threshold voltage adjustment ion layer 13 on the substrate.

At the same time as the etching of the plurality of trenches T, part of the source/drain ion layer 15 is etched. That is, the source/drain ion layer 15 is patterned to form a source/drain 15′.

After removal of the mask 16, as shown in FIG. 2c, polysilicon (not shown) is deposited on the silicon substrate 11 to a sufficient thickness to bury the trenches T.

Finally, the surface of the deposited polysilicon is planarized through a chemical-mechanical polishing process, thereby forming a polysilicon gate electrode 17.

As stated above, in the semiconductor device manufacturing method of the present invention, the threshold voltage adjustment ion layer 13 and the source/drain ion layer 15 are formed prior to formation of the recess gate. This enables the gate and the source/drain to be accurately aligned with each other through the trench forming process without misalignment of the masks for use in the formation of the source/drain and the gate.

Further, the semiconductor device manufacturing method of the present invention does not require an additional masking process for forming the source/drain. This simplifies the general manufacturing process of the semiconductor device, improving the yield of the semiconductor device.

As apparent from the above description, the present invention provides a method of manufacturing a semiconductor device in which a source/drain is formed prior to formation of a gate to thereby eliminate the risk of misalignment of the source/drain, resulting in an increase in the drive-ability of the gate.

Further, the present invention can omit a separate masking process for forming the source/drain, thereby achieving a simplification in the general manufacturing process of the semiconductor device and hence an improvement in the yield of the semiconductor device.

Furthermore, according to the present invention, as a result of using a low voltage in the implantation of source/drain forming ions, it is possible to prevent the production of a defective device due to a high voltage. In the case of DRAM, especially, this can cause an increase in a refresh characteristic of the device, and can reduce degradation of the device due to a hot carrier effect.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method of manufacturing a semiconductor device comprising the steps of:
a) forming a threshold voltage adjustment ion layer having a predetermined depth in an active region of a silicon substrate;
b) implanting source/drain forming ions into the silicon substrate on the threshold voltage adjustment ion layer formed in the silicon substrate;
c) forming a mask for defining a recess trench forming region on the silicon substrate, where in substrate complete the implantation of the source/drain forming ions;
d) forming recess trenches by etching the silicon substrate to a predetermined depth using the mask as an etching mask;
e) depositing polysilicon on the silicon substrate to a thickness sufficient to bury the recess trenches; and
f) forming a gate electrode through planarization of the deposited polysilicon.

2. The method of according to claim 1, wherein the source/drain forming ions are implanted into the silicon substrate by making using a voltage in a range of 10 to 20 KeV.

3. The method of according to claim 1, wherein the bottom of the trenches is higher than the bottom of the threshold voltage adjustment ion layer on the silicon substrate.
